(19) United States
(12) Patent Application Publication
(10) Pub. No.: US 2026/0092198 A1
(43) Pub. Date: Apr. 2, 2026

(54) POLISHING COMPOSITION

(71) Applicant: Fujimi Incorporated, Kiyosu-shi (JP)

(72) Inventors: Atsushi TSUZUKI, Kiyosu-shi (JP); Masashi ABE, Kiyosu-shi (JP)

(73) Assignee: Fujimi Incorporated, Kiyosu-shi (JP)

(21) Appl. No.: 19/330,365

(22) Filed: Sep. 16, 2025

(30) Foreign Application Priority Data
Sep. 27, 2024 (JP) 2024-168522

(51) Int. Cl. C09G 1/16; B24B 37/04; H01L 21/3105

(52) U.S. Cl. CPC C09G 1/16; B24B 37/044; H10P 95/062

(57) ABSTRACT

Provided is a polishing composition that can polish a carbon film at a high polishing removal rate, and can polish the carbon film at a high polishing removal rate with respect to a polishing removal rate of a silicon nitride film. A polishing composition, containing an anion-modified silica particle; a nonionic surfactant; and an anionic polymer, wherein a pH of the polishing composition is 1.0 or more and 5.0 or less.

### TECHNICAL FIELD

The present disclosure relates to a polishing composition.

### BACKGROUND ART

In recent years, due to the multilayered wiring of the surface of a semiconductor substrate, a technology known as Chemical Mechanical Polishing (CMP) technology in which a semiconductor substrate is polished to be flattened at the time of producing a device has been used. CMP is a method in which the surface of an object to be polished such as a semiconductor substrate is flattened by using a polishing composition.

Studies have been continued in the field of the CMP technology in order to achieve a desired effect by polishing.

Japanese Patent Laid-Open No. 2024-092301 discloses that, on a substrate containing silicon oxide and silicon nitride, both silicon oxide and silicon nitride can be polished at a high polishing removal rate with a polishing composition containing an inorganic particle having a specific particle size distribution and having an organic acid immobilized on the surface thereof and an acid compound. Japanese Patent Laid-Open No. 2024-092301 discloses that an object to be polished contains a carbon film.

### SUMMARY

In recent years, with regard to an object to be polished containing a carbon film and a silicon nitride film, there has been a demand for maintaining or enhancing the polishing removal rate of the carbon film and suppressing the polishing removal rate of the silicon nitride film, which is known as controlling the selection ratio of the polishing removal rates.

An object of the present disclosure is to provide a polishing composition that can polish a carbon film at a high polishing removal rate, and can polish the carbon film at a high polishing removal rate with respect to the polishing removal rate of a silicon nitride film (that is, a polishing composition having a high selection ratio represented by Polishing removal rate of carbon film/Polishing removal rate of silicon nitride film).

In order to achieve the object, the present inventors have conducted intensive studies. As a result, they have found the fact that the object can be achieved with a polishing composition containing an anion-modified silica particle; a nonionic surfactant; and an anionic polymer, wherein a pH of the polishing composition is 1.0 or more and 5.0 or less, thereby achieving the present disclosure.

### DESCRIPTION OF EMBODIMENTS

Embodiments of the present disclosure will hereinafter be described, but the present disclosure is not limited to the embodiments described below, and various modifications could be made within the scope of the claims. The embodiments described in the present specification could be arbitrarily combined for another embodiment. In the present specification, unless otherwise specified, operations and measurements of physical properties and the like are performed under the conditions of room temperature (20° C. or more and 25° C. or less)/a relative humidity of 40% RH or more and 50% RH or less.

### <Polishing Composition>

An aspect of the present disclosure relates to a polishing composition containing an anion-modified silica particle; a nonionic surfactant; and an anionic polymer, wherein a pH of the composition is 1.0 or more and 5.0 or less. The polishing composition according to the present disclosure can polish a carbon film at a high polishing removal rate, and can polish the carbon film at a high polishing removal rate with respect to the polishing removal rate of a silicon nitride film (that is, the polishing composition can have a high selection ratio represented by Polishing removal rate of carbon film/Polishing removal rate of silicon nitride film). In the present specification, the phrase “selection ratio represented by Polishing removal rate of carbon film/Polishing removal rate of silicon nitride film” is also simply referred to as “selection ratio of Carbon film/Silicon nitride film”.

### [Anion-Modified Silica Particle]

The polishing composition according to the present disclosure contains an anion-modified silica particle. The anion-modified silica particle is a silica particle having an anionic group. As the anion-modified silica particle, one type thereof may be used alone, or two or more types thereof may be used in combination. As the anion-modified silica particle, a commercially available product may be used, or a synthesized product may be used.

The anion-modified silica particle has negative zeta potential under acidic conditions, and, therefore, is excellent in dispersion stability.

The anion-modified silica particle is not particularly limited, but is preferably an anion-modified colloidal silica (colloidal silica having an anionic group). Examples of the anion-modified colloidal silica include a colloidal silica having an anionic group such as a carboxylic acid group, a sulfonic acid group, a phosphonic acid group, and an aluminate group immobilized on the surface thereof.

The method for producing the anion-modified colloidal silica is not particularly limited, and examples thereof include a method in which a silane coupling agent having an anionic group on the terminal thereof and the colloidal silica are allowed to react with each other.

Examples of the method for producing the colloidal silica include a sodium silicate method and a sol-gel method, and a colloidal silica produced by any production method can be suitably used. However, from the viewpoint of reducing metal impurities, a colloidal silica produced by a sol-gel method is preferred. The colloidal silica produced by a sol-gel method is preferred because the content of metal impurities and/or corrosive ions such as chloride ions dispersible in a semiconductor is small. Production of the colloidal silica by a sol-gel method may be performed by using a conventionally known method. Specifically, the colloidal silica can be obtained by performing hydrolysis condensation reaction using a hydrolysable silicon compound (for example, alkoxysilane or a derivative thereof) as a raw material.

Specific examples of the method for immobilizing the sulfonic acid group on the colloidal silica include a method described in “Sulfonic acid-functionalized silica through quantitative oxidation of thiol groups”, Chem. Commun. 246-247 (2003). Specifically, a colloidal silica having a sulfonic acid group immobilized on the surface thereof (sulfonic acid-modified colloidal silica) can be obtained by coupling a silane coupling agent having a thiol group such as 3-mercaptopropyltrimethoxysilane to the colloidal silica, and then oxidizing the thiol group with hydrogen peroxide. In a preferred embodiment, the anion-modified silica particle contains the sulfonic acid-modified colloidal silica.

Examples of the method for immobilizing the carboxylic acid group on the colloidal silica include a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, a colloidal silica having a carboxylic acid group immobilized on the surface thereof (carboxylic acid-modified colloidal silica) can be obtained by coupling a silane coupling agent containing photoreactive 2-nitrobenzyl ester to the colloidal silica, and then irradiating light thereon.

The average primary particle size of the anion-modified silica particle is not particularly limited, but is preferably 1 nm or more, more preferably 3 nm or more, and further preferably 5 nm or more. The average primary particle size of the anion-modified silica particle is not particularly limited, but is preferably 100 nm or less, more preferably 50 nm or less, and further preferably 30 nm or less. Examples of the preferred average primary particle size of the anion-modified silica particle include 1 nm or more and 100 nm or less, 3 nm or more and 50 nm or less, and 5 nm or more and 30 nm or less. However, the average primary particle size of the anion-modified silica particle is not limited to these ranges. Where the anion-modified silica particle is an anion-modified colloidal silica, the preferred range of the average primary particle size of the anion-modified colloidal silica is the same as the preferred range of the average primary particle size of the anion-modified silica particle as described above. The average primary particle size of the anion-modified silica particle can be calculated based on the specific surface area (SA) of the anion-modified silica particle calculated by the BET method and the density of the anion-modified silica particle. More specifically, the average primary particle size of the anion-modified silica particle can be measured and calculated by the method described in Examples.

The average secondary particle size of the anion-modified silica particle is not particularly limited, but is preferably 15 nm or more, more preferably 20 nm or more, and further preferably 25 nm or more. If the average secondary particle size is within the above range, the resistance during polishing is small, thereby allowing for stable polishing. The average secondary particle size of the anion-modified silica particle is not particularly limited, but is preferably 500 nm or less, more preferably 400 nm or less, and further preferably 300 nm or less. If the average secondary particle size is within the above range, the removal amount of the object to be polished is enhanced, thereby enhancing the polishing removal rate. Examples of the preferred average secondary particle size of the anion-modified silica particle include 15 nm or more and 500 nm or less, 20 nm or more and 400 nm or less, and 25 nm or more and 300 nm or less. However, the average secondary particle size of the anion-modified silica particle is not limited to these ranges. Where the anion-modified silica particle is an anion-modified colloidal silica, the preferred range of the average secondary particle size of the anion-modified colloidal silica is the same as the preferred range of the average secondary particle size of the anion-modified silica particle as described above. The average secondary particle size of the anion-modified silica particle can be measured as a volume-average particle size (arithmetic mean size on volume basis; Mv) by a dynamic light scattering method. More specifically, the average secondary particle size of the anion-modified silica particle can be measured by the method described in Examples.

The ratio of the average secondary particle size to the average primary particle size of the anion-modified silica particle (Average secondary particle size/Average primary particle size) (hereinafter, “the ratio of the average secondary particle size to the average primary particle size” is also referred to as “average degree of association”) is not particularly limited, but is preferably more than 1.0, more preferably 1.1 or more, and further preferably 1.2 or more. The average degree of association of the anion-modified silica particle is not particularly limited, but is preferably 4.0 or less, more preferably 3.5 or less, and further preferably 3.0 or less. Examples of the preferred average degree of association of the anion-modified silica particle include more than 1.0 and 4.0 or less, 1.1 or more and 3.5 or less, and 1.2 or more and 3.0 or less. However, the average degree of association of the anion-modified silica particle is not limited to these ranges. Where the anion-modified silica particle contains an anion-modified colloidal silica, the preferred range of the average degree of association of the anion-modified colloidal silica is the same as the preferred range of the average degree of association of the anion-modified silica particle as described above. The average degree of association of the anion-modified silica particle can be calculated by dividing the value of the average secondary particle size of the anion-modified silica particle by the value of the average primary particle size of the anion-modified silica particle (Value of average secondary particle size of anion-modified silica particle/Value of average primary particle size of anion-modified silica particle).

The shape of the anion-modified silica particle (preferably anion-modified colloidal silica) is not particularly limited, and the shape may be spherical or non-spherical. Specific examples of the non-spherical shape include various shapes such as a polygonal shape such as a triangular prism and a quadrangular prism, a cylindrical shape, a barrel-like shape in which the central part of a column is bulged compared with the end part, a doughnut-like shape in which the central part of a disk is penetrated, a plate-like shape, a shape known as a cocoon-like shape having a constriction in the central part, a shape known as an aggregated-type spherical shape in which a plurality of particles are aggregated into a single body, a shape known as a kompeito-like shape having a plurality of protrusions on the surface, and a rugby ball-like shape, which are not particularly limited.

Each of the shape and the size (the average primary particle size, the average secondary particle size, the average degree of association, and the like) of the anion-modified silica particle can be appropriately controlled by, for example, selection of the method for producing the anion-modified silica particle. However, the method for controlling each of the shape and the size of the anion-modified silica particle is not limited thereto.

The content (concentration) of the anion-modified silica particle in the polishing composition is not particularly limited, but is preferably 0.01 mass % or more, more preferably 0.05 mass % or more, further preferably 0.1 mass % or more, and particularly preferably 0.3 mass % or more based on the total mass of the polishing composition. The content of the anion-modified silica particle in the polishing composition is not particularly limited, but is preferably 10 mass % or less, more preferably 5 mass % or less, further preferably 2 mass % or less, and particularly preferably 1 mass % or less based on the total mass of the polishing composition. If the content is within the above range, the polishing removal rate at the time of polishing a specific object to be polished is enhanced more. Also, if the content is within the above range, a selection ratio for a specific object to be polished with respect to another specific object to be polished is sometimes enhanced more. The preferred content of the anion-modified silica particle in the polishing composition is not particularly limited, but examples thereof include 0.01 mass % or more and 10 mass % or less, 0.05 mass % or more and 5 mass % or less, 0.1 mass % or more and 2 mass % or less, and 0.3 mass % or more and 1 mass % or less based on the total mass of the polishing composition. However, the content of the anion-modified silica particle in the polishing composition is not limited to these ranges.

### [Nonionic Surfactant]

The polishing composition according to the present disclosure contains a nonionic surfactant. As the nonionic surfactant, one type thereof may be used alone, or two or more types thereof may be used in combination. As the nonionic surfactant, a commercially available product may be used, or a synthesized product may be used.

The nonionic surfactant can be adsorbed on the surface of the hydrophobic carbon film to hydrophilize the surface of the carbon film. It is considered that the hydrophilized surface of the carbon film increases in the frequency of contact as a result of interaction between the surface of the carbon film and the anion-modified silica particle, which is hydrophilic, thereby enhancing the polishing removal rate of the carbon film.

Examples of the nonionic surfactant include alkyl betaines, alkyl amine oxides, polyoxyalkylene glycols, polyoxyalkylene alkyl ethers, sorbitan fatty acid esters, glycerol fatty acid esters, polyoxyalkylene fatty acid esters, polyoxyalkylene alkyl amines, and alkyl alkanolamides. The nonionic surfactant is preferably a compound having a polyoxyalkylene glycol structure (also referred to as “polyoxyalkylene glycol compound” in the present specification) such as polyoxyalkylene glycol and polyoxyalkylene alkyl ether from the viewpoint that the effect of the present disclosure can be more effectively exerted.

In a preferred embodiment, the nonionic surfactant contains a compound having a polyoxyalkylene glycol structure. Examples of the compound having a polyoxyalkylene glycol structure include oxyalkylene homopolymers, oxyalkylene copolymers, and polyoxyalkylene alkyl ethers.

The oxyalkylene homopolymers and the oxyalkylene copolymers are not particularly limited, and examples thereof include polyethylene glycol, polypropylene glycol, polyethylene glycol-polypropylene glycol random copolymers, polyethylene glycol-polytetramethylene glycol random copolymers, polypropylene glycol-polytetramethylene glycol random copolymers, polyethylene glycol-polypropylene glycol-polytetramethylene glycol random copolymers, polyethylene glycol-polypropylene glycol block copolymers, polypropylene glycol-polyethylene glycol-polypropylene glycol triblock copolymers, and polyethylene glycol-polypropylene glycol-polyethylene glycol triblock copolymers.

In a more preferred embodiment, the nonionic surfactant contains a compound represented by the following formula 1 as polyoxyalkylene alkyl ether.

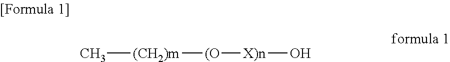

Wherein X is an alkylene group having 2 or 3 carbon atoms; m is an integer of 4 or more and 14 or less; and n is an integer of 3 or more and 25 or less.

In the formula 1, X is preferably an alkylene group having 2 carbon atoms (that is, an ethylene group).

In the formula 1, m is preferably an integer of 5 or more and 12 or less, and more preferably an integer of 7 or more and 9 or less.

In the formula 1, n is preferably an integer of 5 or more and 15 or less, and more preferably an integer of 5 or more and 10 or less.

The compound represented by the formula 1 is preferably at least one selected from the group consisting of polyoxyethylene (5) monooctyl ether, polyoxyethylene (6) monooctyl ether, polyoxyethylene (7) monooctyl ether, polyoxyethylene (8) monooctyl ether, polyoxyethylene (9) monooctyl ether, polyoxyethylene (10) monooctyl ether, polyoxyethylene (5) monononyl ether, polyoxyethylene (6) monononyl ether, polyoxyethylene (7) monononyl ether, polyoxyethylene (8) monononyl ether, polyoxyethylene (9) monononyl ether, polyoxyethylene (10) monononyl ether, polyoxyethylene (5) monodecyl ether, polyoxyethylene (6) monodecyl ether, polyoxyethylene (7) monodecyl ether, polyoxyethylene (8) monodecyl ether, polyoxyethylene (9) monodecyl ether, and polyoxyethylene (10) monodecyl ether.

The content (concentration) of the nonionic surfactant in the polishing composition is not particularly limited, but is preferably 0.001 mass % or more, more preferably 0.005 mass % or more, further preferably 0.01 mass % or more, and particularly preferably 0.05 mass % or more based on the total mass of the polishing composition. The content (concentration) of the nonionic surfactant in the polishing composition is preferably 3 mass % or less, more preferably 1 mass % or less, further preferably 0.5 mass % or less, and particularly preferably 0.1 mass % or less based on the total mass of the polishing composition. The preferred content (concentration) of the nonionic surfactant in the polishing composition is not particularly limited, but examples thereof include 0.001 mass % or more and 3 mass % or less, 0.005 mass % or more and 1 mass % or less, 0.01 mass % or more and 0.5 mass % or less, and 0.05 mass % or more and 0.1 mass % or less based on the total mass of the polishing composition. However, the content (concentration) of the nonionic surfactant in the polishing composition is not limited to these ranges. If the content (concentration) of the nonionic surfactant is within the above range, the effect of the present disclosure can be more effectively exerted.

### [Anionic Polymer]

The polishing composition according to the present disclosure contains an anionic polymer. In the present specification, the term “anionic polymer” refers to a polymer having an anionic group such as a carboxylic acid group, a sulfonic acid group, and a phosphoric acid group in the molecule. As the anionic polymer, one type thereof may be used alone, or two or more types thereof may be used in combination. As the anionic polymer, a commercially available product may be used, or a synthesized product may be used.

It is considered that the anionic group that the anionic polymer has and the silicon nitride film are electrically attracted to each other, whereby the anionic polymer is adsorbed on the surface of the silicon nitride film, whereby the polishing removal rate of the silicon nitride film can be suppressed. It is considered that the anionic polymer has a hydrophobic moiety (such as a main chain) and a hydrophilic moiety (the anionic group), and, therefore, a function similar to that of a surfactant can contribute to enhancing the polishing removal rate of the carbon film.

The anionic polymer may have an anionic group. Specific examples of the anionic polymer acid, include polyvinylsulfonic acid, polystyrenesulfonic acid, polyallylsulfonic polymethallylsulfonic acid, poly(2-acrylamido-2-methylpropanesulfonic acid), polyisoprene sulfonic acid, polyacrylic acid, polymethacrylic acid, (meth)acrylic acid-isoprenesulfonic acid copolymers, (meth)acrylic acid-[2-(meth)acrylamido-2-methylpropanesulfonic acid] copolymers, and (meth)acrylic acid-isoprenesulfonic acid-[2-(meth)acrylamido-2-methylpropanesulfonic acid] copolymers. The anionic polymer may be in the form of a neutralized salt.

As the anionic polymer, not only the anionic polymer having a main chain structure as described above, but also a graft copolymer having an anionic polymer structure on the side chain can be suitably used. The anionic polymer may be a polymer having the same repeating constituting unit (homopolymer) or a polymer having different repeating constituting units (copolymer), and, where the anionic polymer is a copolymer, the form of the copolymer may be any of a block copolymer, a random copolymer, a graft copolymer, or an alternating copolymer.

In a preferred embodiment, the anionic polymer contains an anionic polymer containing a sulfonic acid group. The anionic polymer containing a sulfonic acid group is not particularly limited as long as the polymer has a sulfonic acid group.

Examples of the anionic polymer containing a sulfonic acid group include polyvinylsulfonic acid, polystyrenesulfonic acid, polyallylsulfonic acid, polymethallylsulfonic acid, poly(2-acrylamido-2-methylpropanesulfonic acid), polyisoprene sulfonic acid, (meth)acrylic acid-isoprenesulfonic acid copolymers, (meth)acrylic acid-[2-(meth)acrylamido-2-methylpropanesulfonic acid] copolymers, and (meth)acrylic acid-isoprenesulfonic acid-[2-(meth)acrylamido-2-methylpropanesulfonic acid] copolymers. The anionic polymer containing a sulfonic acid group may be in the form of a neutralized salt.

In a more preferred embodiment, the anionic polymer containing a sulfonic acid group contains poly(2-acrylamido-2-methylpropanesulfonic acid).

The anionic group in the anionic polymer containing a sulfonic acid group may contain a sulfonic acid group alone, or may contain one or more types of anionic groups other than the sulfonic acid group, in addition to the sulfonic acid group.

The weight average molecular weight of the anionic polymer is preferably 1,500 or more, more preferably 3,000 or more, further preferably 4,000 or more, even further preferably 5,000 or more, particularly preferably 6,000 or more, even particularly preferably 7,000 or more, and most preferably 8,000 or more. The weight average molecular weight of the anionic polymer is preferably 1,000,000 or less, more preferably 500,000 or less, further preferably 100,000 or less, even further preferably 50,000 or less, particularly preferably 25,000 or less, even particularly preferably 20,000 or less, and most preferably 15,000 or less. That is, the weight average molecular weight of the anionic polymer is preferably 1,500 or more and 1,000,000 or less, more preferably 3,000 or more and 500,000 or less, further preferably 4,000 or more and 100,000 or less, even further preferably 5,000 or more and 50,000 or less, particularly preferably 6,000 or more and 25,000 or less, even particularly preferably 7,000 or more and 20,000 or less, and most preferably 8,000 or more and 15,000 or less. In the present specification, the weight average molecular weight of the anionic polymer can be measured by gel permeation chromatography (GPC) based on polyethylene glycol as a standard substance. The detailed measurement method is as described in Examples.

The content (concentration) of the anionic polymer in the polishing composition is not particularly limited, but is preferably 0.0001 mass % or more, more preferably 0.0005 mass % or more, further preferably 0.001 mass % or more, and particularly preferably 0.01 mass % or more based on the total mass of the polishing composition. The content (concentration) of the anionic polymer in the polishing composition is preferably 3 mass % or less, more preferably 1 mass % or less, further preferably 0.5 mass % or less, and particularly preferably 0.1 mass % or less based on the total mass of the polishing composition. The preferred content (concentration) of the anionic polymer in the polishing composition is not particularly limited, but examples thereof include 0.0001 mass % or more and 3 mass % or less, 0.0005 mass % or more and 1 mass % or less, 0.001 mass % or more and 0.5 mass % or less, and 0.01 mass % or more and 0.1 mass % or less based on the total mass of the polishing composition. However, the content (concentration) of the anionic polymer in the polishing composition is not limited to these ranges. If the content (concentration) of the anionic polymer is within the above range, the effect of the present disclosure can be more effectively exerted. In a preferred embodiment, the content of the anionic polymer in the polishing composition is smaller than the content of the nonionic surfactant.

### [Ph]

The pH of the polishing composition according to the present disclosure is 1.0 or more and 5.0 or less. If the pH of the polishing composition according to the present disclosure is less than 1.0, there is a possibility that the component contained in the polishing composition is decomposed, which is not preferred. If the pH of the polishing composition according to the present disclosure is more than 5.0, the negative charge of the carbon film increases, causing the polishing removal rate to decrease due to electrostatic repulsion between the carbon film and the anion-modified silica particle, which is not preferred. The pH of the polishing composition according to the present disclosure is preferably 2.0 or more and 4.0 or less, more preferably 2.5 or more and 3.5 or less, and further preferably 2.7 or more and 3.2 or less.

The pH of the polishing composition according to the present disclosure may be adjusted with the anionic polymer or with a pH adjusting agent. In an embodiment, the polishing composition according to the present disclosure may contain a pH adjusting agent. As the pH adjusting agent, one type thereof may be used alone, or two or more types thereof may be used in combination. As the pH adjusting agent, a commercially available product may be used, or a synthesized product may be used.

The pH adjusting agent is not particularly limited, and known pH adjusting agents used in the field of polishing compositions can be used. As the pH adjusting agent, known acids, bases, salts thereof, or the like can be used. Examples of the pH adjusting agent include organic acids such as carboxylic acids such as formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, cicosapentaenoic acid, lactic acid, malic acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acid, and anthranilic acid, sulfonic acid, and organic phosphonic acid; inorganic acids such as nitric acid, carbonic acid, hydrochloric acid, hypophosphorous acid, phosphorous acid, phosphonic acid, boric acid, and hydrofluoric acid; hydroxides of alkali metals such as potassium hydroxide (KOH); carbonates of alkali metals such as potassium carbonate (K₂CO₃) and sodium carbonate (Na₂CO₃); hydroxides of group 2 elements; ammonia (ammonium hydroxide); and organic bases such as quaternary ammonium hydroxide compounds.

The content (concentration) of the pH adjusting agent in the polishing composition may be appropriately selected so that the polishing composition has a desired value of pH.

For the pH in the polishing composition, a value obtained by measurement by the method described in Examples is adopted.

### [Dispersing Medium]

The polishing composition according to the present disclosure may contain a dispersing medium in order to dissolve and/or disperse each component. As the dispersing medium, one type thereof may be used alone, or two or more types thereof may be used in combination.

The dispersing medium is not particularly limited, and examples thereof include water; alcohols such as methanol, ethanol, and ethylene glycol; ketones such as acetone; and mixtures thereof. The dispersing medium is preferably water.

The water is preferably water containing as few impurities as possible from the viewpoint of preventing the impurities from inhibiting the function of the component contained in the polishing composition. The water is preferably water in which the total content of transition metal ions is 100 ppb or less. The purity of the water can be enhanced by operations such as removing impurity ions by using an ion exchange resin, removing foreign matter with a filter, or distillation. The water is more preferably selected from deionized water (ion exchange water), pure water, ultrapure water, and distilled water.

### [Other Components]

The polishing composition according to the present disclosure may further contain other known components that may be used for the polishing composition to an extent that the effect of the present disclosure is not inhibited. Examples of other components include abrasive grains other than the anion-modified silica particle, oxidizing agents, antifungal agents (antiseptic agents), complexing agents, and metal anticorrosives. Hereinafter, the abrasive grains other than the anion-modified silica particle, the oxidizing agents, and the antifungal agents (antiseptic agents) will be described.

The abrasive grain other than the anion-modified silica particle may be any of an inorganic particle, an organic particle, or an organic-inorganic composite particle. Specific examples of the inorganic particle are not particularly limited, and include metal oxide particles such as unmodified silica particles, alumina particles, ceria particles, titania particles; silicon nitride particles; silicon carbide particles; and boron nitride particles. Specific examples of the organic particles are not particularly limited, and include polymethyl methacrylate (PMMA) particles. As the abrasive grain other than the anion-modified silica particle, one type thereof may be used alone, or two or more types thereof may be used in combination.

Examples of the oxidizing agent include hydrogen peroxide, sodium peroxide, barium peroxide, ozonated water, silver (II) salts, iron (III) salts, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, and salts thereof (such as potassium salts, sodium salts, and ammonium salts). As the oxidizing agent, one type thereof may be used alone, or two or more types thereof may be used in combination.

Examples of the antifungal agent (antiseptic agent) include isothiazoline antiseptic agents such as 2-methyl-4-isothiazolin-3-one and 5-chloro-2-methyl-4-isothiazolin-3-one; and phenoxyethanol. As the antifungal agent (antiseptic agent), one type thereof may be used alone, or two or more types thereof may be used in combination.

### [Method for Producing Polishing Composition]

The method for producing the polishing composition according to the present disclosure is not particularly limited, and the polishing composition can be obtained by, for example, stirring and mixing the anion-modified silica particle, the nonionic surfactant, and the anionic polymer, and, as necessary, the pH adjusting agent, the dispersing medium, and other components together. Details of each component are as described above.

The temperature at the time of mixing each of the components together is not particularly limited, and is preferably 10° C. or more and 40° C. or less, and the components may be heated in order to increase the rate of dissolution. Also, the mixing time is not particularly limited as long as homogeneous mixing can be performed.

### [Object to be Polished]

The object to be polished that the polishing composition according to the present disclosure is to polish preferably contains a carbon film and a silicon nitride film. The polishing composition according to the present disclosure is preferably used for polishing an object to be polished containing a carbon film and a silicon nitride film.

In the present specification, the carbon film is not limited to a film composed of a carbon simple substance, and encompasses carbon films containing atoms other than a carbon atom (such as a hydrogen atom and an oxygen atom).

Examples of the carbon film include spin-on carbon films, amorphous carbon films, diamond-like carbon films, nanocrystalline diamond films, graphene films, SiC films, and SiOC films. As the carbon film, one type thereof may be used alone, or two or more types thereof may be used in combination. The carbon film is preferably selected from the group consisting of spin-on carbon films, amorphous carbon films, diamond-like carbon films, nanocrystalline diamond films, and graphene films, and more preferably the carbon film is a spin-on carbon film.

The content of carbon atoms in the carbon film is preferred in the order of 10 mass % or more, 30 mass % or more, 50 mass % or more, 60 mass % or more, 70 mass % or more, 80 mass % or more, 90 mass % or more, 92 mass % or more, 95 mass % or more, 97 mass % or more, 98 mass % or more, and 99 mass % or more based on the total mass of the carbon film. The carbon film may be in the form of being substantially composed of carbon (that is, in the form in which the content of carbon atoms is substantially 100 mass %).

The carbon film and the silicon nitride film can be formed by CVD, PVD, a spin coating method, or the like.

The object to be polished that the polishing composition according to the present disclosure is to polish may further contain other materials in addition to the carbon film and the silicon nitride film. Examples of other materials include silicon oxide, single-crystalline silicon, polycrystalline silicon (polysilicon), non-crystalline silicon (amorphous silicon), polycrystalline silicon doped with n-type or p-type impurities, non-crystalline silicon doped with n-type or p-type impurities, titanium nitride, metal simple substances, and SiGe.

Examples of the object to be polished containing silicon oxide include a TEOS (Tetraethyl Orthosilicate) type silicon oxide film (hereinafter also referred to as “TEOS” or “TEOS film”) formed by using tetraethyl orthosilicate as a precursor, an HDP (High Density Plasma) film, a USG (Undoped Silicate Glass) film, a PSG (Phosphorus Silicate Glass) film, a BPSG (Boron-Phospho Silicate Glass) film, and an RTO (Rapid Thermal Oxidation) film.

Examples of the metal simple substance include tungsten, copper, cobalt, hafnium, nickel, gold, silver, platinum, palladium, rhodium, ruthenium, iridium, and osmium.

### <Polishing Method and Method for Producing Semiconductor Substrate>

An aspect of the present disclosure relates to a polishing method including a step of polishing an object to be polished containing a carbon film and a silicon nitride film by using the polishing composition as described above.

An aspect of the present disclosure relates to a method for producing a semiconductor substrate including a step of polishing a semiconductor substrate containing a carbon film and a silicon nitride film by the polishing method as described above.

The polishing apparatus is not particularly limited, and, for example, a common polishing apparatus having a holder for holding a substrate or the like containing the object to be polished, a motor in which the rotation speed can be changed, and the like provided therein, and having a polishing table to which a polishing pad (polishing cloth) can be sticked can be used as the polishing apparatus.

The polishing pad is not particularly limited, but, for example, common nonwoven fabric, polyurethane, or porous fluororesin can be used as the polishing pad without particular limitation. It is preferred that the polishing pad has been subjected to grooving so that polishing liquid is stored.

The polishing conditions are not particularly limited. For example, with regard to the polishing table and the rotation speed of the head, 10 rpm (0.17 s⁻¹) or more and 500 rpm (8.33 s⁻¹) or less is preferred. For example, the pressure to be applied to the substrate having the object to be polished (polishing pressure) is preferably 0.5 psi (3.4 kPa) or more and 10 psi (68.9 kPa) or less.

The method for supplying the polishing composition to the polishing pad is not particularly limited as well, and, for example, a method in which the polishing composition is continuously supplied with a pump or the like is adopted. The supply amount is not limited, but it is preferred that the surface of the polishing pad is covered with the polishing composition at all times. The polishing time is not particularly limited as well, and, for example, appropriately selecting the time such that desired polishing can be achieved is sufficient.

After finishing polishing, the substrate or the like containing the object to be polished may be cleaned in running water, and then water droplets adhered to the substrate may be removed to dry the substrate by using a spin dryer or the like.

The polishing composition according to the present disclosure may be a one-pack type or a multi-pack type such as a two-pack type. The polishing composition according to the present disclosure may be prepared by diluting the stock solution of the polishing composition to, for example, 3 times or more (or, for example, 5 times or more) by using a diluting liquid such as water.

### [Polishing Removal Rate of Carbon Film, Polishing Removal Rate of Silicon Nitride Film, and Selection Ratio of Carbon Film/Silicon Nitride Film]

With the polishing method according to the present disclosure, an object to be polished containing a carbon film and a silicon nitride film can be polished at a specific ratio of polishing removal rate. The polishing method according to the present disclosure may be preferably applied to polishing (for example, finish polishing) of an object to be polished containing a carbon film and a silicon nitride film.

The lower limit of the polishing removal rate of the carbon film is preferably 200 Å/min or more, more preferably 215 Å/min or more, and further preferably 240 Å/min or more. The upper limit of the polishing removal rate of the carbon film is not particularly limited, and is practically 6000 Å/min or less. 1 Å is equal to 0.1 nm.

The upper limit of the polishing removal rate of the silicon nitride film is preferably 30 Å/min or less, more preferably 20 Å/min or less, and further preferably 10 Å/min or less. The lower limit of the polishing removal rate of the silicon nitride film is not particularly limited, and is, for example, 0.5 Å/min or more.

The selection ratio of Carbon film/Silicon nitride film is preferably 10 or more and more preferably 30 or more. The selection ratio of Carbon film/Silicon nitride film may be 100 or more, 150 or more, or 200 or more.

Embodiments of the present disclosure are described above in detail, but the description is merely illustrative and exemplary and is not limitative. It is clear that the scope of the present disclosure should be interpreted based on the attached claims.

The present disclosure encompasses the following aspects and embodiments.
[1] A polishing composition containing an anion-modified silica particle; a nonionic surfactant; and an anionic polymer, wherein a pH of the polishing composition is 1.0 or more and 5.0 or less.
[2] The polishing composition according to the [1], wherein the anion-modified silica particle is an anion-modified colloidal silica.
[3] The polishing composition according to the [1] or the [2], wherein the nonionic surfactant contains a compound having a polyoxyalkylene glycol structure.
[4] The polishing composition according to the [3], wherein the nonionic surfactant contains a compound represented by the following formula 1.

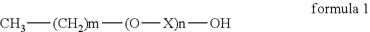

Wherein X is an alkylene group having 2 or 3 carbon atoms; m is an integer of 4 or more and 14 or less; and n is an integer of 3 or more and 25 or less.
[5] The polishing composition according to any of the [1] to the [4], wherein the anionic polymer contains an anionic polymer containing a sulfonic acid group.
[6] The polishing composition according to any of the [1] to the [5] used for polishing an object to be polished containing a carbon film and a silicon nitride film.
[7] A polishing method comprising a step of polishing an object to be polished containing a carbon film and a silicon nitride film by using the polishing composition according to any of the [1] to the [6].
[8] A method for producing a semiconductor substrate comprising a step of polishing a semiconductor substrate containing a carbon film and a silicon nitride film by the polishing method according to the [7].

### EXAMPLES

The present disclosure will be described in more detail with reference to the following Examples and Comparative Example. The technical scope of the present disclosure is not limited to the following Examples. Unless otherwise specified, “%” and “parts” mean “mass %” and “parts by mass”, respectively. Also, unless otherwise specified, operations were performed under the conditions of room temperature (20° C. or more and 25° C. or less)/a relative humidity of 40% RH or more and 50% RH or less.

### <Measurement Method>

### (Average Primary Particle Size of Anion-Modified Silica Particle)

The average primary particle size of the anion-modified silica particle was calculated from the specific surface area of the anion-modified silica particle measured by using “Flow Sorb II 2300” manufactured by Micromeritics Instrument Corporation by BET method and the density of the anion-modified silica particle.

### (Average Secondary Particle Size of Anion-Modified Silica Particle)

The average secondary particle size of the anion-modified silica particle was measured as a volume-average particle size (arithmetic mean size on volume basis; Mv) by using a dynamic light scattering particle size and particle size distribution measurement apparatus UPA-UT151 (manufactured by NIKKISO CO., LTD.)

### (pH of Polishing Composition)

With regard to the pH of the polishing composition, by using a glass electrode type hydrogen ion concentration indicator (manufactured by HORIBA, Ltd.; model: F-23), three-point calibration was performed by using standard buffer solutions (a phthalate pH buffer solution having a pH of 4.01 (25° C.), a neutral phosphate pH buffer solution having a pH of 6.86 (25° C.), and a carbonate pH buffer solution having a pH of 10.01 (25° C.)), and then the glass electrode was placed in the polishing composition for 2 minutes or more to allow the pH value to become stable. The pH value after the value became stable was defined as the pH value of the polishing composition.

### (Weight Average Molecular Weight)

For the weight average molecular weight (Mw) of the anionic polymer, a value of the weight average molecular weight (based on polyethylene glycol) obtained by measurement by gel permeation chromatography (GPC) was used. The weight average molecular weight was measured with the following apparatus under the following conditions:
GPC apparatus: manufactured by SHIMADZU CORPORATION
Model: Prominence+ELSD (ELSD-LTII)
Column: VP-ODS (manufactured by SHIMADZU CORPORATION)
Mobile phase A: MeOH
B: 1% aqueous solution of acetic acid
Flow rate: 1 mL/minute
Detector: ELSD temp. 40° C.; Gain 8; N2GAS 350 kPa
Oven temperature: 40° C.
Injecting amount: 40 μL.

### Comparative Example 1

A sulfonic acid-modified colloidal silica (average primary particle size: 15 nm; average secondary particle size: 34 nm) was added to pure water as a dispersing medium so that the final concentration would be 0.4 mass %. Further, polyoxyethylene (10) decyl ether as a nonionic surfactant was added thereto so that the final concentration would be 0.08 mass %, and then the resulting solution was stirred and mixed for 30 minutes at room temperature (25° C.). Thereafter, nitric acid was added thereto so that the pH would be 2.9 to prepare a polishing composition.

### Example 1

A sulfonic acid-modified colloidal silica (average primary particle size: 15 nm; average secondary particle size: 34 nm) was added to pure water as a dispersing medium so that the final concentration would be 0.4 mass %. Further, polyoxyethylene (10) monodecyl ether as a nonionic surfactant was added thereto so that the final concentration would be 0.08 mass %, and sodium salt of a copolymer of acrylic acid and 2-acrylamido-2-methylpropanesulfonic acid (weight average molecular weight: 12,000) (hereinafter referred to as “(acrylic acid/sulfonic acid) copolymer”) as an anionic polymer was added thereto so that the final concentration would be 0.002 mass %. Then, the resulting solution was stirred and mixed for 30 minutes at room temperature (25° C.). Thereafter, nitric acid was added thereto so that the pH would be 2.9 to prepare a polishing composition.

### Example 2

A sulfonic acid-modified colloidal silica (average primary particle size: 15 nm; average secondary particle size: 34 nm) was added to pure water as a dispersing medium so that the final concentration would be 0.4 mass %. Further, polyoxyethylene (10) monodecyl ether as a nonionic surfactant was added thereto so that the final concentration would be 0.08 mass %, and sodium salt of an (acrylic acid/sulfonic acid) copolymer (weight average molecular weight: 12,000) as an anionic polymer was added thereto so that the final concentration would be 0.05 mass %. Then, the resulting solution was stirred and mixed for 30 minutes at room temperature (25° C.) to prepare a polishing composition (pH: 2.9).

The constitution of each polishing composition is shown in Table 1. In Table 1, “-” indicates that the component was not used.

TABLE 1

| | | Nonionic | Anionic | |
|---|---|---|---|---|
| | Anion-modified silica | surfactant | polymer | |
| | particle [mass %] | [mass %] | [mass %] | pH |
| Comparative | 0.4 | 0.08 | — | 2.9 |
| Example 1 | | | | |
| Example 1 | 0.4 | 0.08 | 0.002 | 2.9 |
| Example 2 | 0.4 | 0.08 | 0.05 | 2.9 |

### <Evaluation>

The surface of the object to be polished was polished under the following conditions by using each polishing composition prepared in the above manner. As the object to be polished, a silicon wafer having a spin-on carbon (SoC) film having a thickness of 2,000 Å formed on the surface thereof (manufactured by Advanced Materials Technology, Inc.; 300 mm; blanket wafer) and a silicon wafer having a silicon nitride (Si₃N₄) film having a thickness of 2,500 Å formed on the surface thereof (manufactured by Advanced Materials Technology, Inc.; 300 mm; blanket wafer) were used.

### (Polishing Apparatus and Polishing Conditions)

Polishing apparatus: Polishing apparatus manufactured by EBARA CORPORATION (model: FREX 300E)
Polishing pad: Suede pad manufactured by NITTA DuPont Incorporated; Supreme RN-H
Polishing pressure: 1.5 psi (1 psi=6894.76 Pa)
Conditioner (dresser): Nylon brush manufactured by 3M Company
Rotation speed of polishing table: 40 rpm
Rotation speed of head: 40 rpm
Supply of polishing composition: continuous supply
Supply amount of polishing composition: 200 mL/minute
Polishing time: 30 seconds (SoC film); 1 minute (silicon nitride film)

### (Evaluation of Polishing Removal Rate)

The thicknesses before and after polishing of the SoC film and the Si₃N₄ film were determined with an optical film thickness measurement apparatus (ASET-f5x: manufactured by KLA Corporation). Based on the determined thicknesses, [(Thickness before polishing [unit: Å])−(Thickness after polishing [unit: Å])] was divided by the polishing time [unit: min] to calculate the polishing removal rate [unit: A/min] for each object to be polished. In the present disclosure, if the polishing removal rate for the SoC film is 200 Å/min or more, the SoC film can be practically used. In the present disclosure, if the polishing removal rate for the Si₃N₄ film is 10 Å/min or less, the Si₃N₄ film can be practically used. A higher selection ratio for the SoC film with respect to the Si₃N₄ film (Polishing removal rate for SoC film/Polishing removal rate for Si₃N₄ film) (described as “SoC/Si₃N₄” in Table 2 below) was evaluated as being more satisfactory.

### (Evaluation of Defects)

The total number of defects (residues) having a size of 85 nm or more (SoC film) or 50 nm or more (Si₃N₄ film) remaining on the surface of the damaged object after polishing was measured by using Surfscan (R) SP-5 manufactured by KLA Corporation.

The result of evaluation of the polishing removal rate and the defects is shown in Table 2. In Table 2, “overload” indicates that the number of defects was too large (more than 300000), and, therefore, measurement was not possible.

TABLE 2

| | Polishing removal rate | | Selection ratio | Number of defects (number) | |
|---|---|---|---|---|---|
| | SoC film | Si₃N₄ film | SoC/Si₃N₄ | SoC film | Si₃N₄ film |
| Comparative Example 1 | 211 | 179 | 1.2 | overload | overload |
| Example 1 | 216 | 6 | 36.0 | 173815 | 50216 |
| Example 2 | 251 | 1 | 251.0 | 42751 | 146 |

As is clear from Table 2, it is shown that, where the polishing compositions according to Examples are used, the SoC film can be polished at a high polishing removal rate compared with the case where the polishing composition according to Comparative Example is used. Also, it is shown that, where the polishing compositions according to Examples are used, the polishing removal rate of the Si₃N₄ film can be significantly suppressed compared with the case where the polishing composition according to Comparative Example is used, and, therefore, the selection ratio for the SoC film with respect to the Si₃N₄ film can be significantly increased.

Comparison between Example 1 and Example 2 shows that the selection ratio for the SoC film with respect to the Si₃N₄ film becomes higher and the number of defects decreases when the content of the anionic polymer is increased.

The present application is based on Japanese Patent Application No. 2024-168522, filed on Sep. 27, 2024, the entire contents of which being herein incorporated by reference.

1. A polishing composition, comprising an anion-modified silica particle; a nonionic surfactant; and an anionic polymer, wherein a pH of the polishing composition is 1.0 or more and 5.0 or less.

2. The polishing composition according to claim 1, wherein the anion-modified silica particle is an anion-modified colloidal silica.

3. The polishing composition according to claim 1, wherein the nonionic surfactant comprises a compound having a polyoxyalkylene glycol structure.

4. The polishing composition according to claim 3, wherein the nonionic surfactant comprises a compound represented by the following formula 1: 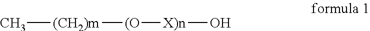
wherein X is an alkylene group having 2 or 3 carbon atoms; m is an integer of 4 or more and 14 or less; and n is an integer of 3 or more and 25 or less.

5. The polishing composition according to claim 1, wherein the anionic polymer comprises an anionic polymer containing a sulfonic acid group.

6. The polishing composition according to claim 1 used for polishing an object to be polished containing a carbon film and a silicon nitride film.

7. A polishing method, comprising a step of polishing an object to be polished containing a carbon film and a silicon nitride film by using the polishing composition according to claim 1.

8. A method for producing a semiconductor substrate, comprising a step of polishing a semiconductor substrate containing a carbon film and a silicon nitride film by the polishing method according to claim 7.
